(19) United States
(12) Patent Application Publication
(10) Pub. No.: US 2024/0164178 A1
(43) Pub. Date: May 16, 2024

(54) DISPLAY DEVICE AND METHOD OF MANUFACTURING SAME

(71) Applicant: SAMSUNG DISPLAY CO., LTD., Yongin-si (KR)

(72) Inventor: Chungi YOU, Yongin-si (KR)

(21) Appl. No.: 18/235,468

(22) Filed: Aug. 18, 2023

(30) Foreign Application Priority Data
Nov. 16, 2022 (KR) 10-2022-0153814

(51) Int. Cl. H10K 59/80; H10K 59/12; H10K 59/35

(52) U.S. Cl. CPC H10K 59/80518; H10K 59/1201; H10K 59/35; H10K 59/80517

(57) ABSTRACT

A display device includes: a substrate including a first pixel including a first pixel electrode including a first reflective layer and a first conductive layer and a first emission layer disposed on the first pixel electrode, a second pixel including a second pixel electrode including a second reflective layer and a second conductive layer and a second emission layer disposed on the second pixel electrode, a third pixel including a third pixel electrode including a third reflective layer and a third conductive layer and a third emission layer disposed on the third pixel electrode, and an opposite electrode disposed on the first to third emission layers. The first conductive layer has a first thickness in a thickness direction of the substrate, and the second conductive layer has a second thickness less than the first thickness in the thickness direction.

This application claims priority to Korean Patent Application No. 10-2022-0153814, filed on Nov. 16, 2022, and all the benefits accruing therefrom under 35 U.S.C. § 119, the content of which in its entirety is herein incorporated by reference.

### BACKGROUND

### 1. Field

One or more embodiments relate to a display device and a method of manufacturing the display device.

### 2. Description of the Related Art

An organic light-emitting display device has attracted attention as a next-generation display device by being lightweight and thin and having advantages such as a wide viewing angle, fast response speed, and low power consumption.

In the case of an organic light-emitting device that implements full color, a light resonance structure that changes the optical length of each wavelength emitted from an organic emission layer of each pixel of a different color is employed.

### SUMMARY

One or more embodiments include a display device with improved light extraction efficiency and a method of manufacturing the same. However, these aspects are exemplary, and the scope of the disclosure is not limited thereto.

Additional aspects will be set forth in part in the description which follows and, in part, will be apparent from the description, or may be learned by practice of the presented embodiments of the disclosure.

According to one or more embodiments, a display device includes: a substrate including a first pixel, a second pixel, and a third pixel, a first pixel electrode of the first pixel, which includes a first reflective layer and a first conductive layer, a second pixel electrode of the second pixel, which includes a second reflective layer and a second conductive layer, and a third pixel electrode of the third pixel, which includes a third reflective layer and a third conductive layer, where the first pixel electrode, the second pixel electrode, and the third pixel electrode are disposed on the substrate, a first emission layer of the first pixel, which is disposed on the first pixel electrode, a second emission layer of the second pixel, which is disposed on the second pixel electrode, and a third emission layer of the third pixel, which is disposed on the third pixel electrode, and an opposite electrode disposed on the first emission layer, the second emission layer, and the third emission layer, where the first conductive layer has a first thickness in a thickness direction of the substrate, and the second conductive layer has a second thickness less than the first thickness in the thickness direction of the substrate.

According to an embodiment, the third conductive layer may have a third thickness less than the second thickness in the thickness direction of the substrate.

According to an embodiment, the first thickness of the first conductive layer may be equal to or greater than 1700 angstrom (Å) and equal to or less than 1900 Å, the second thickness of the second conductive layer may be equal to or greater than 1100 Å and equal to or less than 1300 Å, and the third thickness of the third conductive layer may be equal to or greater than 600 Å and equal to or less than 800 Å.

According to an embodiment, the display device may further include a capping layer disposed on the opposite electrode.

According to an embodiment, the first emission layer, the second emission layer, and the third emission layer may emit red light, green light, and blue light, respectively.

According to an embodiment, the first conductive layer, the second conductive layer, and the third conductive layer may include a same material.

According to an embodiment, the first reflective layer, the second reflective layer, and the third reflective layer may include a same material.

According to an embodiment, the first conductive layer, the second conductive layer, and the third conductive layer may be disposed on the first reflective layer, the second reflective layer, and the third reflective layer, respectively.

According to an embodiment, the display device may further include a first protective layer, a second protective layer, and a third protective layer directly disposed on lower surfaces of the first reflective layer, the second reflective layer, and the third reflective layer, respectively.

According to an embodiment, the first protective layer, the second protective layer, and the third protective layer may include a same material.

According to one or more embodiments, a method of manufacturing a display device includes: disposing a material for forming a partition layer on a substrate, forming a partition layer by patterning the material for forming the partition layer, disposing a material for forming a reflective layer and a material for forming a conductive layer on the partition layer and in openings defined in the partition layer, forming a first pixel electrode including a first reflective layer and a first conductive layer, a second pixel electrode including a second reflective layer and a second conductive layer, and a third pixel electrode including a third reflective layer and a third conductive layer by removing the material for forming the reflective layer and the material for forming the conductive layer, which are disposed on the partition layer, performing first etching in which at least a portion of the second conductive layer and the third conductive layer are wet-etched after forming a first mask pattern to cover and surround the first pixel electrode, removing the first mask pattern, and performing second etching in which at least a portion of the third conductive layer is wet-etched after forming a second mask pattern to cover and surround each of the first pixel electrode and the second pixel electrode.

According to an embodiment, the method may further include, after performing the second etching in which at least the portion of the third conductive layer is wet-etched after forming the second mask pattern to cover and surround each of the first pixel electrode and the second pixel electrode, removing the second mask pattern.

According to an embodiment, the material for forming the partition layer may include an inorganic material.

According to an embodiment, the material for forming the partition layer may include a photoresist-forming material.

According to an embodiment, the method may further include, after the forming of the first to third pixel electrodes, removing the partition layer.

According to an embodiment, a thickness of each of the first conductive layer, the second conductive layer, and the third conductive layer before performing the first etching may be equal to or greater than 1700 Å and equal to or less than 1900 Å.

According to an embodiment, the first conductive layer after performing the second etching may have a first thickness in a thickness direction of the substrate, the second conductive layer after performing the second etching may have a second thickness less than the first thickness in the thickness direction of the substrate, and the third conductive layer after performing the second etching may have a third thickness less than the second thickness in the thickness direction of the substrate.

According to an embodiment, the first thickness of the first conductive layer after performing the second etching may be equal to or greater than 1700 Å and equal to or less than 1900 Å, the second thickness of the second conductive layer after performing the second etching may be equal to or greater than 1100 Å and equal to or less than 1300 Å, and the third thickness of the third conductive layer after performing the second etching may be equal to or greater than 600 Å and equal to or less than 800 Å.

According to an embodiment, the method may further include disposing a first emission layer, a second emission layer, and a third emission layer on the first pixel electrode, the second pixel electrode, and the third pixel electrode, respectively, where the first emission layer, the second emission layer, and the third emission layer may emit red light, green light, and blue light, respectively.

According to an embodiment, the method may further include disposing an opposite electrode on the first emission layer, the second emission layer, and the third emission layer, and disposing a capping layer on the opposite electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic cross-sectional view of a display device according to an embodiment;

FIG. 3 is a schematic cross-sectional view of a pixel circuit layer in the cross-sectional view of the display device according to the embodiment of FIG. 2;

FIG. 4 is a schematic equivalent circuit diagram illustrating an organic light-emitting diode and a pixel circuit electrically connected to the organic light-emitting diode included in a display device according to an embodiment;

FIGS. 5 to 15 are cross-sectional views schematically illustrating a method of manufacturing a display device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein.

Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or component is referred to as being formed on another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.” In addition, “at least one of A and B” or “at least one selected from A and B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

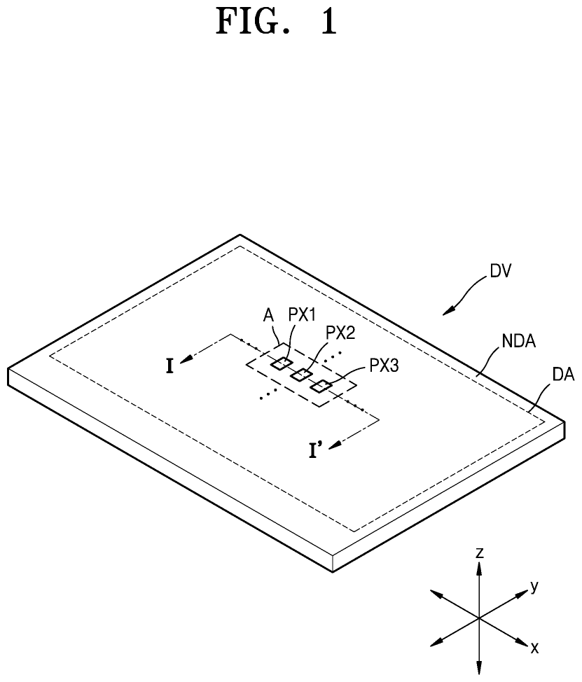

FIG. 1 is a schematic perspective view of a display device DV according to an embodiment.

Referring to FIG. 1, the display device DV may include a display area DA and a non-display area NDA outside the display area DA. The display device DV may provide an image through an array of a plurality of pixels PX, which are two-dimensionally arranged on an x-y plane in the display area DA. The plurality of pixels PX may include a first pixel PX1, a second pixel PX2, and a third pixel PX3. The first pixel PX1, the second pixel PX2, and the third pixel PX3 may emit light of different wavelength bands, respectively. For example, the first pixel PX1 may emit green light, the second pixel PX2 may emit red light, and the third pixel PX3 may emit blue light. However, the disclosure is not limited thereto. The display device DV may provide an image by using light emitted from the plurality of pixels PX.

The non-display area NDA is an area which does not provide an image, and may surround the entirety of the display area DA. A driver or a main voltage line, which is configured to provide electrical signals or power to pixel circuits, may be arranged in the non-display area NDA. A pad, which is an area to which an electronic device or a printed circuit board may be electrically connected, may be arranged in the non-display area NDA.

The display area DA may have a polygonal shape including a quadrangular shape, as shown in FIG. 1. For example, the display area DA may have a rectangular shape in which a horizontal length is greater than a vertical length, a rectangular shape in which a horizontal length is less than a vertical length, or a square shape. Alternatively, the display area DA may have various shapes, such as an oval shape or a circular shape.

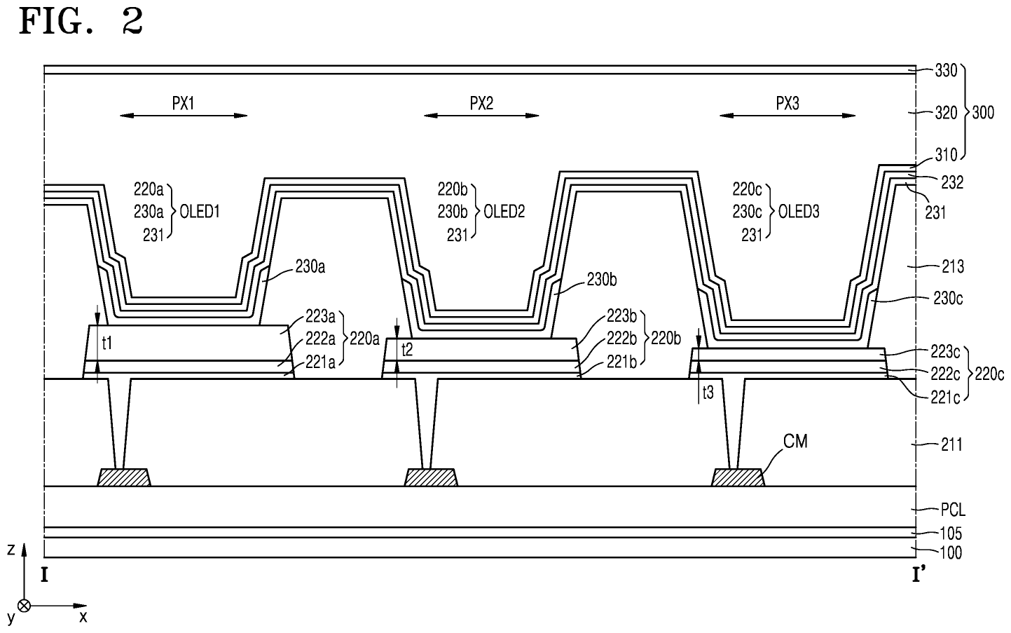

FIG. 2 is a schematic cross-sectional view of a display device according to an embodiment. In particular, FIG. 2 schematically illustrates a cross-sectional view of the display device according to an embodiment of FIG. 1, taken along line I-I′.

Referring to FIG. 2, the first pixel PX1, the second pixel PX2, and the third pixel PX3 may be disposed on a substrate 100. The first pixel PX1, the second pixel PX2, and the third pixel PX3 may include a first organic light-emitting diode OLED1, a second organic light-emitting diode OLED2, and a third organic light-emitting diode OLED3, respectively. The first organic light-emitting diode OLED1 of the first pixel PX1 may include a first pixel electrode 220a, a first emission layer 230a, and an opposite electrode 231, the second organic light-emitting diode OLED2 of the second pixel PX2 may include a second pixel electrode 220b, a second emission layer 230b, and the opposite electrode 231, and the third organic light-emitting diode OLED3 of the third pixel PX3 may include a third pixel electrode 220c, a third emission layer 230c, and the opposite electrode 231.

In an embodiment, the first to third pixel electrodes 220a, 220b, and 220c may be disposed on a second organic insulating layer 211. The first pixel electrode 220a may include a first protective layer 221a, a first reflective layer 222a, and a first conductive layer 223a. The first protective layer 221a, the first reflective layer 222a, and the first conductive layer 223a may be stacked in a thickness direction (i.e., z direction) of the substrate 100. The first reflective layer 222a may be disposed on the first protective layer 221a, and the first conductive layer 223a may be disposed on the first reflective layer 222a. In other words, the first protective layer 221a may directly be disposed on a lower surface of the first reflective layer 222a. The second pixel electrode 220b may include a second protective layer 221b, a second reflective layer 222b, and a second conductive layer 223b. The second protective layer 221b, the second reflective layer 222b, and the second conductive layer 223b may be stacked in the thickness direction of the substrate 100. The second reflective layer 222b may be disposed on the second protective layer 221b, and the second conductive layer 223b may be disposed on the second reflective layer 222b. In other words, the second protective layer 221b may directly be disposed on a lower surface of the second reflective layer 222b. The third pixel electrode 220c may include a third protective layer 221c, a third reflective layer 222c, and a third conductive layer 223c. The third protective layer 221c, the third reflective layer 222c, and the third conductive layer 223c may be stacked in the thickness direction of the substrate 100. The third reflective layer 222c may be disposed on the third protective layer 221c, and the third conductive layer 223c may be disposed on the third reflective layer 222c. In other words, the third protective layer 221c may directly be disposed on a lower surface of the third reflective layer 222c.

The first to third protective layers 221a, 221b, and 221c of the first to third pixel electrodes 220a, 220b, and 220c may each include titanium (Ti). The first to third protective layers 221a, 221b, and 221c may prevent the materials of the first to third pixel electrodes 220a, 220b, and 220c and the material of the second organic insulating layer 211 disposed below the first to third pixel electrodes 220a, 220b, and 220c from being mixed with each other, and may protect the second organic insulating layer 211 disposed below the first to third protective layers 221a, 221b, and 221c. The first to third reflective layers 222a, 222b, and 222c of the first to third pixel electrodes 220a, 220b, and 220c may each include silver (Ag), magnesium (Mg), aluminum (AI), platinum (Pt), palladium (Pd), gold (Au), nickel (Ni), neodymium (Nd), iridium (Ir), chromium (Cr), or a compound thereof. In particular, in an embodiment, the first to third reflective layers 222a, 222b, and 222c may each include Al. The first to third conductive layers 223a, 223b, and 223c of the first to third pixel electrodes 220a, 220b, and 220c may each include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In particular, in an embodiment, the first to third conductive layers 223a, 223b, and 223c may each include ITO. However, the disclosure is not limited thereto.

A pixel defining layer 213 may be disposed on the first to third pixel electrodes 220a, 220b, and 220c. The pixel defining layer 213 may include openings each exposing at least a portion of an upper surface of the first to third pixel electrodes 220a, 220b, and 220c, and may cover the edges of the first to third pixel electrodes 220a, 220b, and 220c.

An opening area of the pixel defining layer 213, which exposes at least a portion of the first pixel electrode 220a, may be an area of the first pixel PX1, an opening area of the pixel defining layer 213, which exposes at least a portion of the second pixel electrode 220b, may be an area of the second pixel PX2, and an opening area of the pixel defining layer 213, which exposes at least a portion of the third pixel electrode 220c, may be an area of the third pixel PX3.

The pixel defining layer 213 may include an inorganic material. The pixel defining layer 213 may include a single layer or a multi-layer, each including silicon oxide (SiOₓ), silicon nitride (SiNₓ), and/or silicon oxynitride (SiON). However, the disclosure is not limited thereto. The pixel defining layer 213 may include an organic material. The pixel defining layer 213 may include one or more organic insulating materials selected from a group consisting of polyimide, polyamide, an acrylic resin layer, benzocyclobutene, and a phenol resin layer.

The first to third emission layers 230a, 230b, and 230c may be disposed on the first to third pixel electrodes 220a, 220b, and 220c, respectively. In particular, the first to third emission layers 230a, 230b, and 230c may disposed on the first to third pixel electrodes 220a, 220b, and 220c and inner surfaces of the pixel defining layer 213 that are the inner surfaces forming the openings of the pixel defining layer 213, respectively. The first to third emission layers 230a, 230b, and 230c may each include a polymer organic material or a low-molecular-weight organic material, which emits light of a certain color.

Although not illustrated in FIG. 2, a first functional layer may be disposed below the first to third emission layers 230a, 230b, and 230c, and a second functional layer may be disposed above the first to third emission layers 230a, 230b, and 230c. The first functional layer and the second functional layer may be continuously disposed on the substrate 100. However, the disclosure is not limited thereto.

The first functional layer may include a single layer or a multi-layer. For example, when the first functional layer includes a polymer material, the first functional layer may be a hole transport layer (“HTL”) having a single-layered structure, and may include poly-(3,4)-ethylene-dihydroxy thiophene (“PEDOT”) or polyaniline (“PANI”). When the first functional layer includes a low-molecular-weight material, the first functional layer may include a hole injection layer (“HIL”) and an HTL.

The second functional layer may be omitted. For example, when each of the first functional layer and the first to third emission layers 230a, 230b, and 230c includes a polymer material, the second functional layer is preferably formed. The second functional layer may include a single layer or a multi-layer. The second functional layer may include an electron transport layer (“ETL”) and/or an electron injection layer (“EIL”).

The first to third emission layers 230a, 230b, and 230c may each be arranged for each pixel in the display area DA. The first to third emission layers 230a, 230b, and 230c may be patterned to correspond to the first to third pixel electrodes 220a, 220b, and 220c, respectively.

In an embodiment, the opposite electrode 231 may be disposed on the first to third emission layers 230a, 230b, and 230c. The opposite electrode 231 may be continuously disposed on the substrate 100.

The opposite electrode 231 may include a conductive material having a low work function. For example, the opposite electrode 231 may include a (semi)transparent layer, the (semi)transparent layer including Ag, Mg, Al, Pt, Pd, Au, Ni, Nd, Ir, Cr, lithium (Li), calcium (Ca), alloys thereof, or the like. Alternatively, the opposite electrode 231 may further include a layer, such as ITO, IZO, ZnO, or In₂O₃, above the (semi)transparent layer including the materials stated above. The first functional layer, the second functional layer, and the opposite electrode 231 may be formed by a thermal deposition method.

The first to third organic light-emitting diodes OLED1, OLED2, and OLED3 may form a microcavity, and the first to third pixel electrodes 220a, 220b, and 220c may be reflective electrodes. In particular, light may be reflected by the first to third reflective layers 222a, 222b, and 222c of the first to third pixel electrodes 220a, 220b, and 220c. That is, the display device DV may be the display device DV in which light emitted from the first to third emission layers 230a, 230b, and 230c is emitted to the outside through the opposite electrode 231.

A capping layer 232 may be disposed on the opposite electrode 231. The capping layer 232 may lithium fluoride (LiF) and may be formed by a thermal deposition method. When the capping layer 232 is not disposed on the opposite electrode 231, reflectance of light emitted from the first to third emission layers 230a, 230b, and 230c at the opposite electrode 231 may be lowered. Accordingly, resonance efficiency of the mircrocavity formed by the first to third pixel electrodes 220a, 220b, and 220c and the opposite electrode 231 may be lowered, and as a result, light extraction efficiency of the display device DV may be reduced. However, the disclosure is not limited thereto.

Light emitted from the first to third emission layers 230a, 230b, and 230c may be emitted through the opposite electrode 231, or may be emitted by being reflected by the opposite electrode 231 and the first to third pixel electrodes 220a, 220b, and 220c. Among the light emitted by the first to third emission layers 230a, 230b, and 230c, light passing through the opposite electrode 231 and light emitted by being reflected by the opposite electrode 231 and the first to third pixel electrodes 220a, 220b, and 220c may form constructive interference to cause a resonance phenomenon, and as a result, light extraction efficiency of the first to third emission layers 230a, 230b, and 230c may be improved. To improve the light extraction efficiency of the first to third emission layers 230a, 230b, and 230c, a distance between the first to third pixel electrodes 220a, 220b, and 220c and the opposite electrode 231 may be set to satisfy a constructive interference condition. Wavelengths of light emitted from the first to third emission layers 230a, 230b, and 230c may be different from each other. In particular, the first emission layer 230a may emit red light, the second emission layer 230b may emit green light, and the third emission layer 230c may emit blue light. Because a resonance distance of light may be determined according to a wavelength of light, a resonance distance of light, which is emitted by the first emission layer 230a, between the first pixel electrode 220a and the opposite electrode 231, a resonance distance of light, which is emitted by the second emission layer 230b, between the second pixel electrode 220b and the opposite electrode 231, and a resonance distance of light, which is emitted by the third emission layer 230c, between the third pixel electrode 220c and the opposite electrode 231 may be different from each other.

In particular, light emitted by the first to third emission layers 230a, 230b, and 230c may be emitted through the opposite electrode 231, or may be reflected by the opposite electrode 231 and the first to third reflective layers 222a, 222b, and 222c of the first to third pixel electrodes 220a, 220b, and 220c. In other words, a resonance distance of light emitted from the first to third emission layers 230a, 230b, and 230c may be a resonance distance between the first to third reflective layers 222a, 222b, and 222c of the first to third pixel electrodes 220a, 220b, and 220c and the opposite electrode 231. In particular, a resonance distance of light emitted from the first emission layer 230a may be a resonance distance between the first reflective layer 222a of the first pixel electrode 220a and the opposite electrode 231, a resonance distance of light emitted from the second emission layer 230b may be a resonance distance between the second reflective layer 222b of the second pixel electrode 220b and the opposite electrode 231, and a resonance distance of light emitted from the third emission layer 230c may be a resonance distance between the third reflective layer 222c of the third pixel electrode 220c and the opposite electrode 231.

The first to third conductive layers 223a, 223b, and 223c may be disposed on the first to third reflective layers 222a, 222b, and 222c of the first to third pixel electrodes 220a, 220b, and 220c, respectively. In other words, a thickness of the first conductive layer 223a of the first pixel electrode 220a may adjust the resonance distance of light emitted from the first emission layer 230a, a thickness of the second conductive layer 223b of the second pixel electrode 220b may adjust the resonance distance of light emitted from the second emission layer 230b, and a thickness of the third conductive layer 223c of the third pixel electrode 220c may adjust the resonance distance of light emitted from the third emission layer 230c.

In an embodiment, the first conductive layer 223a of the first pixel electrode 220a may have a first thickness t1 in the thickness direction of the substrate 100, the second conductive layer 223b of the second pixel electrode 220b may have a second thickness t2 in the thickness direction of the substrate 100, and the third conductive layer 223c of the third pixel electrode 220c may have a third thickness t3 in the thickness direction of the substrate 100. The second thickness t2 of the second conductive layer 223b of the second pixel electrode 220b may be less than the first thickness t1 of the first conductive layer 223a of the first pixel electrode 220a. In addition, the third thickness t3 of the third conductive layer 223c of the third pixel electrode 220c may be less than the second thickness t2 of the second conductive layer 223b of the second pixel electrode 220b. In other words, the first thickness t1 of the first conductive layer 223a of the first pixel electrode 220a may be the greatest, and the third thickness t3 of the third conductive layer 223c of the third pixel electrode 220c may be the smallest. The second thickness t2 of the second conductive layer 223b of the second pixel electrode 220b may be intermediate between the first thickness t1 and the third thickness t3. In particular, the first thickness t1 of the first conductive layer 223a of the first pixel electrode 220a may be greater than or equal to 1700 angstrom (Å) and less than or equal to 1900 Å, the second thickness t2 of the second conductive layer 223b of the second pixel electrode 220b may be greater than or equal to 1100 Å and less than or equal to 1300 Å, and the third thickness t3 of the third conductive layer 223c of the third pixel electrode 220c may be greater than or equal to 600 Å or less than or equal to 800 Å. However, the disclosure is not limited thereto.

A resonance distance of light emitted from the first emission layer 230a may be determined according to the thickness of the first conductive layer 223a of the first pixel electrode 220a. In other words, when the thickness of the first conductive layer 223a of the first pixel electrode 220a satisfies a range of 1700 Å or more and 1900 Å or less, light emitted by the first emission layer 230a through the opposite electrode 231 and light emitted from the first emission layer 230a and reflected by the opposite electrode 231 and the first reflective layer 222a may form constructive interference with each other to cause a resonance phenomenon, and thus light extraction efficiency of the first emission layer 230a may be improved. A resonance distance of light emitted from the second emission layer 230b may be determined according to the thickness of the second conductive layer 223b of the second pixel electrode 220b. In other words, when the thickness of the second conductive layer 223b of the second pixel electrode 220b satisfies a range of 1100 Å or more and 1300 Å or less, light emitted by the second emission layer 230b through the opposite electrode 231 and light emitted from the second emission layer 230b and reflected by the opposite electrode 231 and the second reflective layer 222b may form constructive interference with each other to cause a resonance phenomenon, and thus light extraction efficiency of the second emission layer 230b may be improved.

A resonance distance of light emitted from the third emission layer 230c may be determined according to the thickness of the third conductive layer 223c of the third pixel electrode 220c. In other words, when the thickness of the third conductive layer 223c of the third pixel electrode 220c satisfies a range of 600 Å or more and 800 Å or less, light emitted by the third emission layer 230c through the opposite electrode 231 and light emitted from the third emission layer 230c and reflected by the opposite electrode 231 and the third reflective layer 222c may form constructive interference with each other to cause a resonance phenomenon, and thus light extraction efficiency of the third emission layer 230c may be improved.

In an embodiment, the first to third pixel electrodes 220a, 220b, and 220c may include the first to third protective layers 221a, 221b, and 221c, the first to third reflective layers 222a, 222b, and 222c, and the first to third conductive layers 223a, 223b, and 223c, respectively. As described above, thicknesses of the first conductive layer 223a of the first pixel electrode 220a, the second conductive layer 223b of the second pixel electrode 220b, and the third conductive layer 223c of the third pixel electrode 220c may be different from each other in the thickness direction of the substrate 100. However, thicknesses of the first reflective layer 222a of the first pixel electrode 220a, the second reflective layer 222b of the second pixel electrode 220b, and the third reflective layer 222c of the third pixel electrode 220c may be equal to each other in the thickness direction of the substrate 100. Also, thicknesses of the first protective layer 221a of the first pixel electrode 220a, the second protective layer 221b of the second pixel electrode 220b, and the third protective layer 221c of the third pixel electrode 220c may be equal to each other in the thickness direction of the substrate 100. Thicknesses of the first emission layer 230a, the second emission layer 230b, and the third emission layer 230c may be equal to each other in the thickness direction of the substrate 100. However, the disclosure is not limited thereto.

The first to third organic light-emitting diodes OLED1, OLED2, and OLED3 may be covered with a thin-film encapsulation layer 300. The thin-film encapsulation layer 300 may include at least one organic encapsulation layer and at least one inorganic encapsulation layer, and FIG. 2 illustrates that the thin-film encapsulation layer 300 includes first and second inorganic encapsulation layers 310 and 330, and an organic encapsulation layer 320 therebetween. In another embodiment, the number of organic encapsulation layers, the number of inorganic encapsulation layers, and a stacking order thereof may be changed.

The first inorganic encapsulation layer 310 and the second inorganic encapsulation layer 330 may each include one or more inorganic materials, such as aluminum oxide, titanium oxide, tantalum oxide, hafnium oxide, zinc oxide, silicon oxide, silicon nitride, silicon oxynitride. The first inorganic encapsulation layer 310 and the second inorganic encapsulation layer 330 may be a single layer or a multi-layer, each including the material stated above. The organic encapsulation layer 320 may include a polymer-based material. The polymer-based material may include an acrylic resin, such as polymethyl methacrylate and polyacrylic acid, an epoxy resin, polyimide, polyethylene, or the like. In an embodiment, the organic encapsulation layer 320 may include an acrylate polymer.

Materials of the first inorganic encapsulation layer 310 and the second inorganic encapsulation layer 330 may be different from each other. For example, the first inorganic encapsulation layer 310 may include silicon oxynitride, and the second inorganic encapsulation layer 330 may include silicon nitride. Thicknesses of the first inorganic encapsulation layer 310 and the second inorganic encapsulation layer 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be equal to each other.

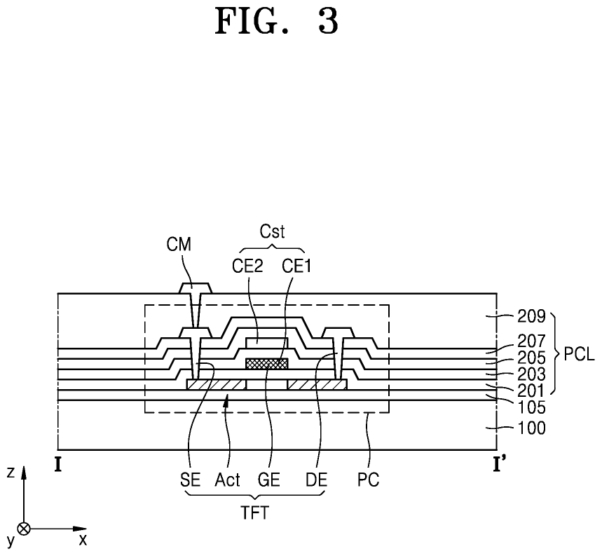

FIG. 3 is a schematic cross-sectional view of a pixel circuit layer in the cross-sectional view of the display device according to the embodiment of FIG. 2.

Referring to FIG. 3, a buffer layer 105 and a pixel circuit PC may be disposed on the substrate 100. Each of the first to third organic light-emitting diodes OLED1, OLED2, and OLED3 may implement an image by emitting light through the pixel circuit PC of a pixel circuit layer PCL. The substrate 100 may include a glass material or a polymer resin.

When the substrate 100 includes a polymer resin, the substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

Although not illustrated in FIG. 3, the substrate 100 may include a first base layer, a first barrier layer, a second base layer, and a second barrier layer. In an embodiment, the first base layer, the first barrier layer, the second base layer, and the second barrier layer may sequentially be stacked in the thickness direction of the substrate 100.

The first barrier layer and the second barrier layer are barrier layers configured to prevent penetration of external foreign substances, and may be a single layer or a multi-layer, each including an inorganic material, such as silicon nitride (SiNₓ), silicon oxide (SiOₓ), and/or silicon oxynitride (SiON).

The buffer layer 105 may be disposed on the substrate 100 to prevent impurities from penetrating into a semiconductor layer Act of a thin-film transistor TFT. The buffer layer 105 may include an inorganic insulating material, such as silicon nitride, silicon oxynitride, and silicon oxide, and may be a single layer or a multi-layer, each including the inorganic insulating material stated above.

The pixel circuit layer PCL may be disposed on the buffer layer 105. The pixel circuit layer PCL may include the pixel circuit PC. The pixel circuit PC may include the thin-film transistor TFT and a storage capacitor Cst. The thin-film transistor TFT may include the semiconductor layer Act, a gate electrode GE, a source electrode SE, and a drain electrode DE. In an embodiment, a top-gate type in which the gate electrode GE is above the semiconductor layer Act with a first insulating layer 201 therebetween is shown, but according to another embodiment, the thin-film transistor TFT may be a bottom-gate type.

The semiconductor layer Act may include polysilicon. Alternatively, the semiconductor layer Act may include amorphous silicon, an oxide semiconductor, an organic semiconductor, or the like. The gate electrode GE may include a low-resistance metal material. The gate electrode GE may include a conductive material including Mo, Al, Cu, Ti, or the like, and may be a multi-layer or a single layer, each including the material stated above.

The first insulating layer 201 between the semiconductor layer Act and the gate electrode GE may include an inorganic insulating material, such as silicon oxide, silicon nitride, silicon oxynitride, aluminum oxide, titanium oxide, tantalum oxide, hafnium oxide, or the like. The first insulating layer 201 may be a single layer or a multi-layer, each including the material stated above.

The source electrode SE and the drain electrode DE may each include a material with good conductivity. The source electrode SE and the drain electrode DE may each include a conductive material including Mo, Al, Cu, Ti, or the like, and may include a multi-layer or a single layer, each including the above material. In an embodiment, the source electrode SE and the drain electrode DE may each have a multi-layered structure of a titanium layer, an aluminum layer, and a titanium layer (Ti/AI/Ti).

The storage capacitor Cst may include a lower electrode CE1 and an upper electrode CE2, which overlap each other with a second insulating layer 203 therebetween. The storage capacitor Cst may overlap the thin-film transistor TFT in a plan view. In this regard, FIG. 3 illustrates that the gate electrode GE of the thin-film transistor TFT is the lower electrode CE1 of the storage capacitor Cst. In another embodiment, the storage capacitor Cst may not overlap the thin-film transistor TFT in a plan view. The storage capacitor Cst may be covered with a third insulating layer 205. The upper electrode CE2 of the storage capacitor Cst may include a conductive material including Mo, Al, Cu, Ti, or the like, and may be a multi-layer or a single layer, each including the material stated above.

A fourth insulating layer 207 may be disposed on the third insulating layer 205. The second insulating layer 203, the third insulating layer 205, and the fourth insulating layer 207 may each include an inorganic insulating material, such as silicon oxide, silicon nitride, silicon oxynitride, aluminum oxide, titanium oxide, tantalum oxide, hafnium oxide, or the like. The second insulating layer 203, the third insulating layer 205, and the fourth insulating layer 207 may each be a single layer or a multi-layer, each including the material stated above.

The pixel circuit PC including the thin-film transistor TFT and the storage capacitor Cst may be covered with a first organic insulating layer 209. An upper surface of the first organic insulating layer 209 may be substantially flat.

The pixel circuit PC may be electrically connected to a pixel electrode 220 (refer to FIG. 2). For example, as shown in FIG. 2, a connection electrode CM may be between the thin-film transistor TFT and the pixel electrode 220. The connection electrode CM may be connected to the thin-film transistor TFT through a contact hole formed in the first organic insulating layer 209, and the pixel electrode 220 may be connected to the connection electrode CM through a contact hole formed in a second organic insulating layer 211 (refer to FIG. 2) on the connection electrode CM. The connection electrode CM may include a conductive material including Mo, Al, Cu, Ti, or the like, and may include a multi-layer or a single layer, each including the above material. In an embodiment, the connection electrode CM may be formed as a multi-layer of Ti/AI/Ti.

The first organic insulating layer 209 and the second organic insulating layer 211 may each include a general commercial polymer such as poly(methyl methacrylate) (“PMMA”) or polystyrene (“PS”), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof. In an embodiment, the first organic insulating layer 209 and the second organic insulating layer 211 may each include polyimide.

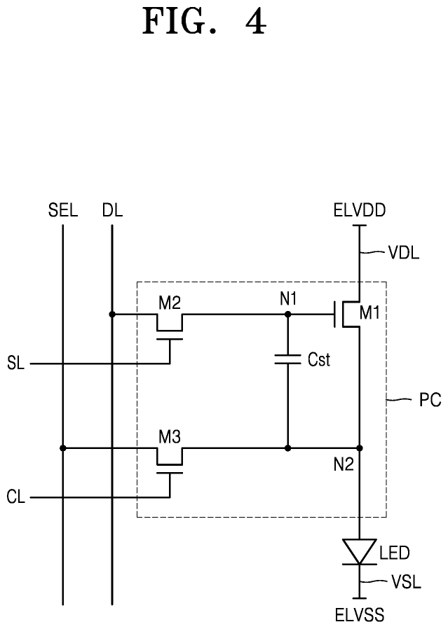

FIG. 4 is a schematic equivalent circuit diagram illustrating an organic light-emitting diode and a pixel circuit electrically connected to the organic light-emitting diode included in a display device according to an embodiment.

Referring to FIG. 4, an organic light-emitting diode (“OLED”), for example, a first pixel electrode (e.g., an anode) of the organic light-emitting diode OLED, may be connected to the pixel circuit PC, and an opposite electrode (e.g., a cathode) of the organic light-emitting diode LED may be connected to a common voltage line VSL providing a common power supply voltage ELVSS. The organic light-emitting diode OLED may emit light having a brightness corresponding to an amount of current supplied from the pixel circuit PC.

The organic light-emitting diode OLED of FIG. 4 may correspond to the organic light-emitting diode OLED shown in FIG. 2, and the pixel circuit PC of FIG. 4 may correspond to the pixel circuit PC shown in FIG. 3.

The pixel circuit PC may control an amount of current flowing from a driving power supply voltage ELVDD to the common power supply voltage ELVSS through the organic light-emitting diode OLED, in response to a data signal. The pixel circuit PC may include a driving transistor M1, a switching transistor M2, a sensing transistor M3, and a storage capacitor Cst.

Each of the driving transistor M1, the switching transistor M2, and the sensing transistor M3 may be an oxide semiconductor thin-film transistor including a semiconductor layer including an oxide semiconductor, or a silicon semiconductor thin-film transistor including a semiconductor layer including polysilicon. Each of the driving transistor M1, the switching transistor M2, and the sensing transistor M3 may include a source electrode (or a source area) and a drain electrode (or a drain area).

The source electrode (or the source area) of the driving transistor M1 may be connected to a driving voltage line VDL supplying the driving power supply voltage ELVDD, and the drain electrode (or the drain area) thereof may be connected to the first pixel electrode (e.g., the anode) of the organic light-emitting diode OLED. A gate electrode of the driving transistor M1 may be connected to a first node N1. The driving transistor M1 may control an amount of current flowing through the organic light-emitting diode OLED from the driving power supply voltage ELVDD in response to a voltage of the first node N1, but positions of the source electrode (or the source area) and the drain electrode (or the drain area) may be changed.

The switching transistor M2 may be a switching transistor. The source electrode (or the source area) of the switching transistor M2 may be connected to a data line DL, and the drain electrode (or the drain area) thereof may be connected to the first node N1. A gate electrode of the switching transistor M2 may be connected to a scan line SL. The switching transistor M2 may be turned on when a scan signal is supplied to the scan line SL to electrically connect the data line DL and the first node N1 to each other. However, positions of the source electrode (or the source area) and the drain electrode (or the drain area) may be changed.

The sensing transistor M3 may be an initialization transistor and/or a sensing transistor. The drain electrode (or the drain area) of the sensing transistor M3 may be connected to a second node N2, and the source electrode (or the source area) thereof may be connected to a sensing line SEL. A gate electrode of the sensing transistor M3 may be connected to a control line CL. However, positions of the source electrode (or the source area) and the drain electrode (or the drain area) may be changed.

The storage capacitor Cst may be connected between the first node N1 and the second node N2. For example, a first capacitor electrode of the storage capacitor Cst may be connected to the gate electrode of the driving transistor M1, and a second capacitor electrode of the storage capacitor Cst may be connected to the first electrode (e.g., the anode) of the organic light-emitting diode LED.

Although FIG. 4 illustrates each of the driving transistor M1, the switching transistor M2, and the sensing transistor M3 as an N-channel metal-oxide-semiconductor (“NMOS”), the disclosure is not limited thereto. For example, at least one of the driving transistor M1, the switching transistor M2, and the sensing transistor M3 may be formed as a p-channel metal-oxide semiconductor (“PMOS”).

Although three transistors are shown in FIG. 4, the disclosure is not limited thereto. The pixel circuit PC may include four or more transistors.

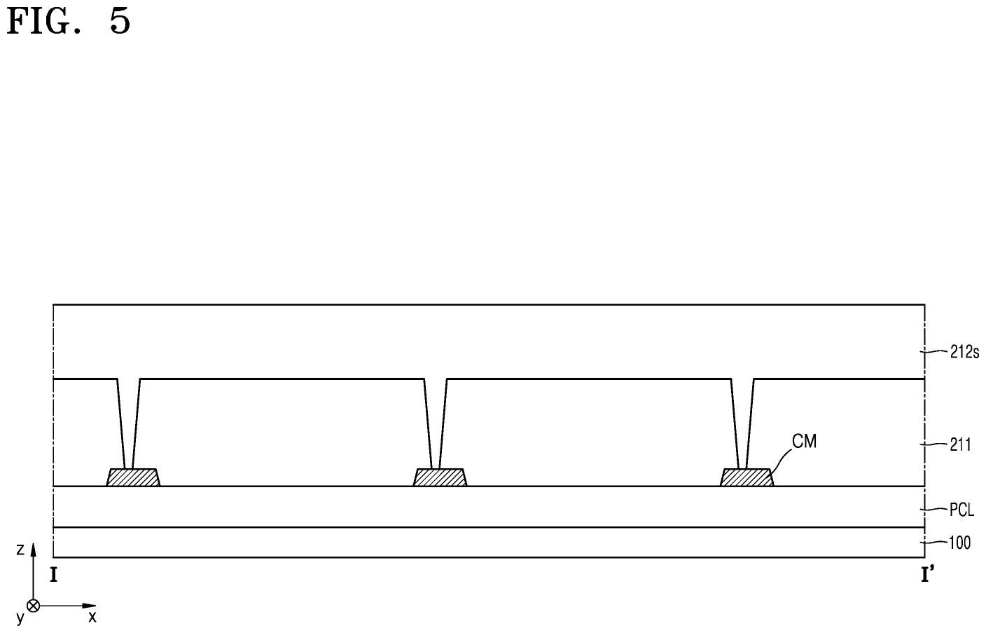

FIGS. 5 to 15 are cross-sectional views schematically illustrating a method of manufacturing a display device.

Referring to FIGS. 5 to 15, a method of manufacturing the display device DV may include: disposing a material 212s for forming a partition layer above the substrate 100, forming a partition layer 212 by patterning the material 212s for forming a partition layer 212, disposing a material 222s for forming a reflective layer and a material 223s for forming a conductive layer on the partition layer 212 and in openings defined in the partition layer 212, forming the first pixel electrode 220a including the first reflective layer 222a and the first conductive layer 223a, the second pixel electrode 220b including the second reflective layer 222b and the second conductive layer 223b, and the third pixel electrode 220c including the third reflective layer 222c and the third conductive layer 223c by planarizing the material 222s for forming a reflective layer and the material 223s for forming a conductive layer, which are disposed on the partition layer 212 and arranged in openings of the partition layer 212, to the same height, performing first etching in which at least a portion of the second conductive layer 223b and the third conductive layer 223c is wet-etched after a first mask pattern MP1 is formed to cover and surround the first pixel electrode 220a, removing the first mask pattern MP1, and performing second etching in which at least a portion of the third conductive layer 223c is wet-etched after a second mask pattern MP2 is formed to cover and surround each of the first pixel electrode 220a and the second pixel electrode 220b.

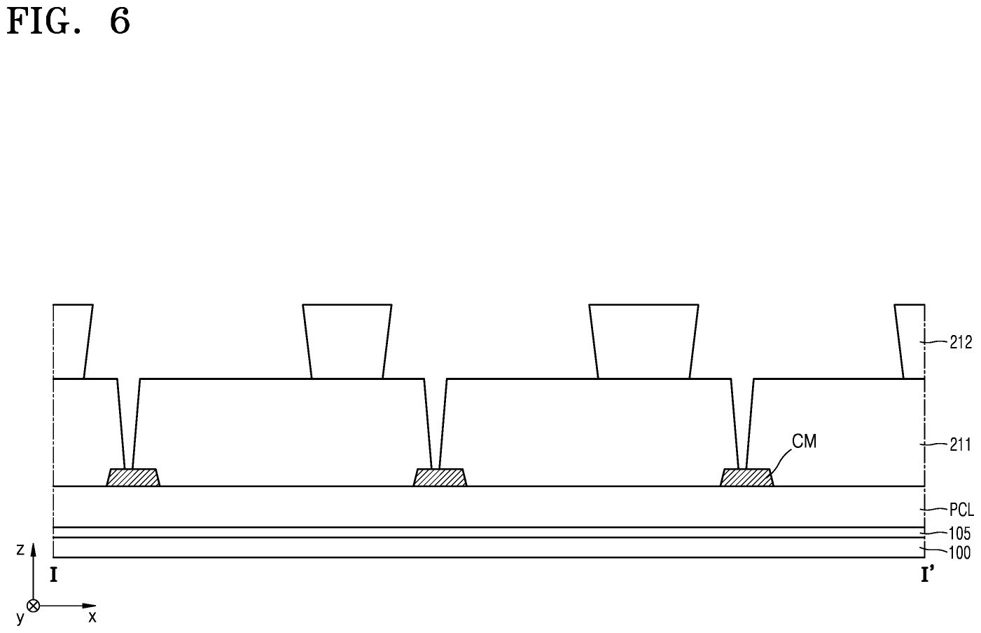

Referring to FIGS. 5 and 6, the pixel circuit layer PCL including the pixel circuit PC for emitting light from the first to third organic light-emitting diodes OLED1, OLED2, and OLED3 may be disposed on the substrate 100. Connection electrodes CM electrically connecting the pixel circuit PC and the first to third pixel electrodes 220a, 220b, and 220d to each other, respectively, may be disposed on the pixel circuit layer PCL. The second organic insulating layer 211 may be disposed on the connection electrodes CM. The connection electrodes CM and the first to third pixel electrodes 220a, 220b, and 220c may be electrically connected to each other through contact holes defined in the second organic insulating layer 211, respectively, so that the first to third organic light-emitting diodes OLED1, OLED2, and OLED3 may emit light.

The material 212s for forming a partition layer may be disposed on the second organic insulating layer 211. The material 212s for forming a partition layer may include a photoresist-forming material. In particular, the material 212s for forming a partition layer may include a negative-type photoresist-forming material. Alternatively, the material 212s for forming a partition layer may include an inorganic material. When the material 212s for forming a partition layer includes an inorganic material, the material 212s for forming a partition layer may include silicon oxide (SiOₓ), silicon nitride (SiNₓ), and/or silicon oxynitride (SiON). However, the disclosure is not limited thereto.

A photoresist may be divided into a negative type and a positive type. In a positive-type photoresist, a portion thereof exposed to light may be dissolved in a developing solution, and in a negative-type photoresist, a portion thereof not exposed to light may be dissolved. In the case of the negative-type photoresist, a photoresist pattern may be formed in a tapered shape. In particular, in a pattern of the negative-type photoresist, a length of an edge close to the substrate 100 in a first direction (e.g., x direction or −x direction) may be short, and a length of an edge far from the substrate 100 in the first direction (e.g., x direction or −x direction) may be long. In other words, when the material 212s for forming a partition layer includes a negative-type photoresist-forming material, the partition layer 212 may be formed in a tapered shape. The partition layer 212 may be formed to have a short length of edge close to the substrate 100 in the first direction (e.g., x direction or −x direction) and a long length of edge far away from the substrate 100 in the first direction (e.g., x direction or −x direction). The partition layer 212 may include openings. At least a portion of the second organic insulating layer 211 may be exposed by the openings of the partition layer 212. However, the disclosure is not limited thereto.

In an embodiment, when the material 212s for forming a partition layer includes an inorganic material, the partition layer 212 may not have a tapered shape. Although not illustrated in drawings, the partition layer 212 may be formed in a rectangular shape rather than a tapered shape. In other words, in the partition layer 212, a length of an edge close to the substrate 100 in the first direction (e.g., x direction or −x direction) may be equal to a length of an edge far away from the substrate 100 in the first direction (e.g., x direction or −x direction). Even when the material 212s for forming a partition layer includes an inorganic material, the partition layer 212 may include openings. At least a portion of the second organic insulating layer 211 may be exposed by the openings of the partition layer 212.

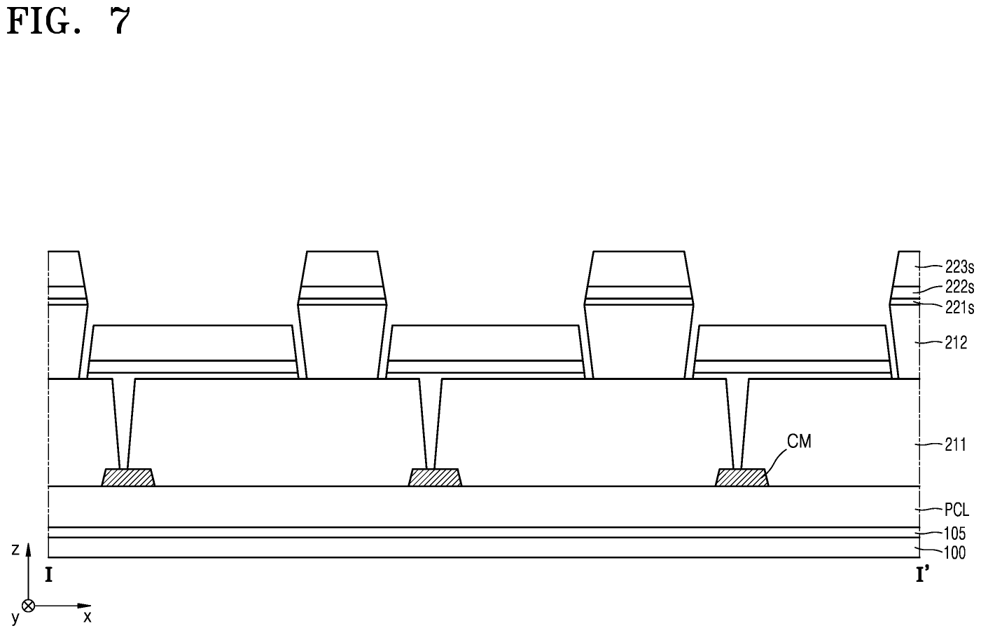

Referring to FIG. 7, after the partition layer 212 is formed, a material 221s for forming a protective layer, the material 222s for forming a reflective layer, and the material 223s for forming a conductive layer may be disposed on the partition layer 212 and arranged in the openings of the partition layer 212. In other words, the material 221s for forming a protective layer, the material 222s for forming the reflective layer, and the material 223s for forming a conductive layer may be disposed on the partition layer 212 and the second organic insulating layer 211 exposed by the openings of the partition layer 212 by a sputtering method. In particular, the material 222s for forming the reflective layer may be disposed on the material 221s for forming a protective layer, and the material 223s for forming a conductive layer may be disposed on the material 222s for forming the reflective layer.

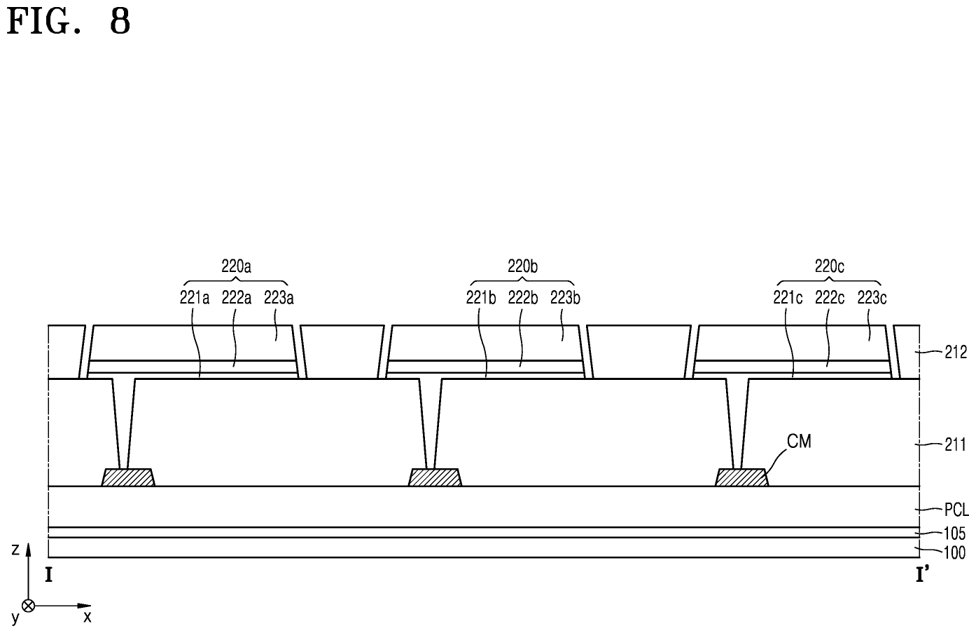

Referring to FIG. 8, the partition layer 212, and the stacked structure including the material 221s for forming a protective layer, the material 222s for forming a reflective layer, and the material 223s for forming a conductive layer, which are disposed in the openings defined in the partition layer 212, may be planarized, such that the partition layer 212, and the stacked structure including the material 221s for forming a protective layer, the material 222s for forming a reflective layer, and the material 223s for forming a conductive layer may have the same thickness in the thickness direction of the substrate 100. Through a planarization process, the material 221s for forming a protective layer, the material 222s for forming a reflective layer, and the material 223s for forming a conductive layer, which are disposed on the partition layer 212, may be removed.

Through the planarization process, the first pixel electrode 220a, the second pixel electrode 220b, and the third pixel electrode 220c may be formed. After the planarization process, the material 221s for forming a protective layer, the material 222s for forming a reflective layer, and the material 223s for forming a conductive layer, which are arranged in at least one of the openings of the partition layer 212, may become the first protective layer 221a, the first reflective layer 222a, and the first conductive layer 223a, respectively, and the first protective layer 221a, the first reflective layer 222a, and the first conductive layer 223a may form the first pixel electrode 220a. After the planarization process, the material 221s for forming a protective layer, the material 222s for forming a reflective layer, and the material 223s for forming a conductive layer, which are arranged in at least one of the openings of the partition layer 212, may become the second protective layer 221b, the second reflective layer 222b, and the second conductive layer 223b, respectively, and the second protective layer 221b, the second reflective layer 222b, and the second conductive layer 223b may form the second pixel electrode 220b. Also, after the planarization process, the material 221s for forming a protective layer, the material 222s for forming a reflective layer, and the material 223s for forming a conductive layer, which are arranged in at least one of the openings of the partition layer 212, may become the third protective layer 221c, the third reflective layer 222c, and the third conductive layer 223c, respectively, and the third protective layer 221c, the third reflective layer 222c, and the third conductive layer 223c may form the third pixel electrode 220c.

After the planarization process, thicknesses of the first conductive layer 223a of the first pixel electrode 220a, the second conductive layer 223b of the second pixel electrode 220b, and the third conductive layer 223c of the third pixel electrode 220c may be equal to each other in the thickness direction of the substrate 100. The thicknesses of the first conductive layer 223a of the first pixel electrode 220a, the second conductive layer 223b of the second pixel electrode 220b, and the third conductive layer 223c of the third pixel electrode 220c may be equal to each other in the thickness direction of the substrate 100 before first wet etching and second wet etching. In particular, after the planarization process, a thickness t1 of the first conductive layer 223a, a thickness t2′ of the second conductive layer 223b, and a thickness t3″ of the third conductive layer 223c may each be 1700 Å or more and 1900 Å or less. Before the first wet etching and the second wet etching, the thickness t1 of the first conductive layer 223a, the thickness t2′ of the second conductive layer 223b, and the thickness t3″ of the third conductive layer 223c may each be 1700 Å or more and 1900 Å or less.

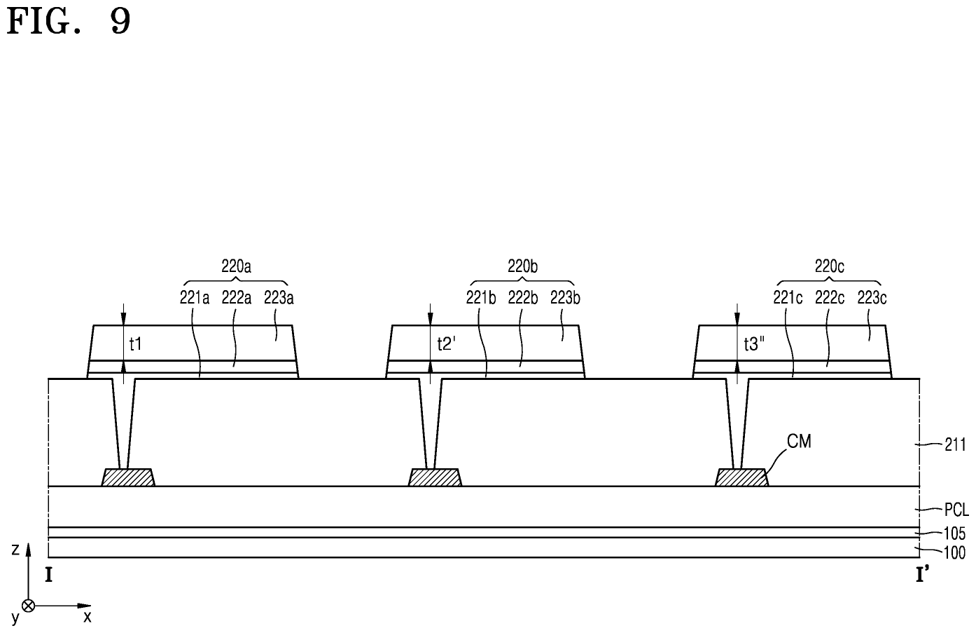

Referring to FIG. 9, the partition layers 212 between the first to third pixel electrodes 220a, 220b, and 220c may be removed. In particular, the partition layer 212 may be removed by dry etching. A process of removing the partition layer 212 may be necessary only when the partition layer 212 includes a photoresist-forming material. When the partition layer 212 includes an inorganic material, although not illustrated, the partition layers 212 between the first to third pixel electrodes 220a, 220b, and 220c may not be removed.

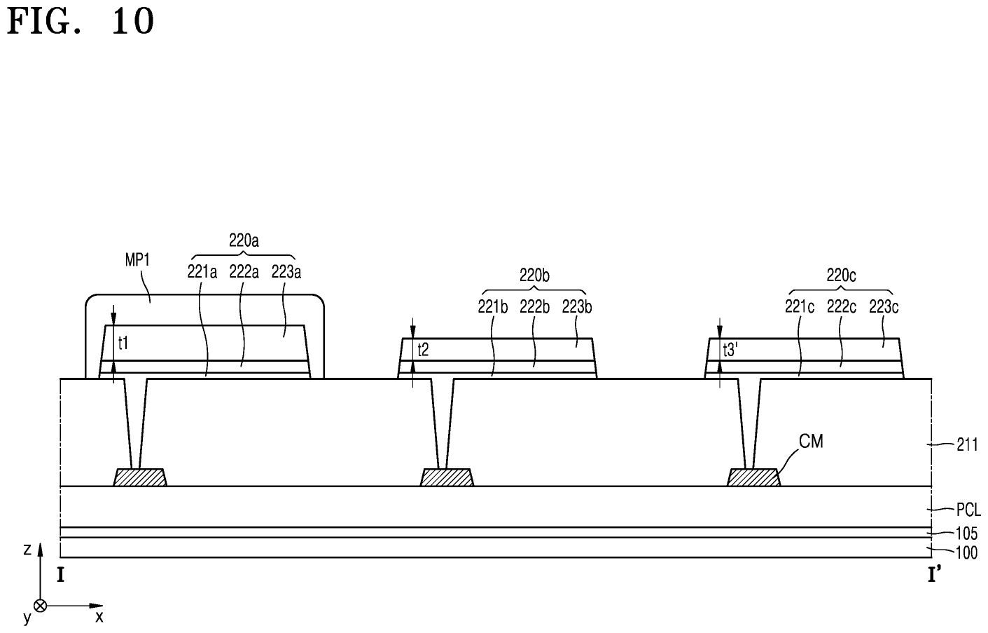

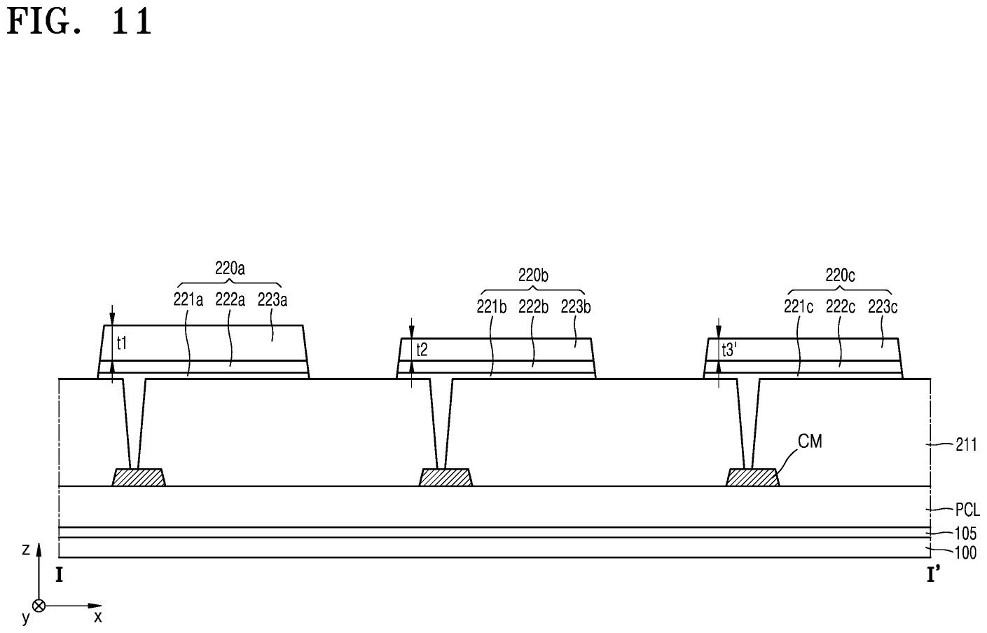

Referring to FIGS. 10 and 11, the first wet etching may be performed after the first mask pattern MP1 is formed to cover and surround the first pixel electrode 220a. The first wet etching may include etching the second conductive layer 223b and the third conductive layer 223c except for the first conductive layer 223a. The first mask pattern MP1 may be formed to cover and surround the first pixel electrode 220a to prevent the first conductive layer 223a of the first pixel electrode 220a from being etched while the second conductive layer 223b of the second pixel electrode 220b and the third conductive layer 223c of the third pixel electrode 220c are wet-etched. The first mask pattern MP1 may be a positive-type photoresist. However, the disclosure is not limited thereto.

In an embodiment, during the first wet etching, the second conductive layer 223b of the second pixel electrode 220b and the third conductive layer 223c of the third pixel electrode 220c may be etched to a thickness of about 600 Å in the thickness direction of the substrate 100. After the first wet etching, a thickness t2 of the second conductive layer 223b of the second pixel electrode 220b and a thickness t3′ of the third conductive layer 223c of the third pixel electrode 220c may be 1100 Å or more and 1300 Å or less.

After the first wet etching is performed, the first mask pattern MP1 may be removed. The first mask pattern MP1 is formed to cover and surround the first pixel electrode 220a, so that the thickness t1 of the first conductive layer 223a may be 1700 Å or more and 1900 Å or less after the first wet etching.

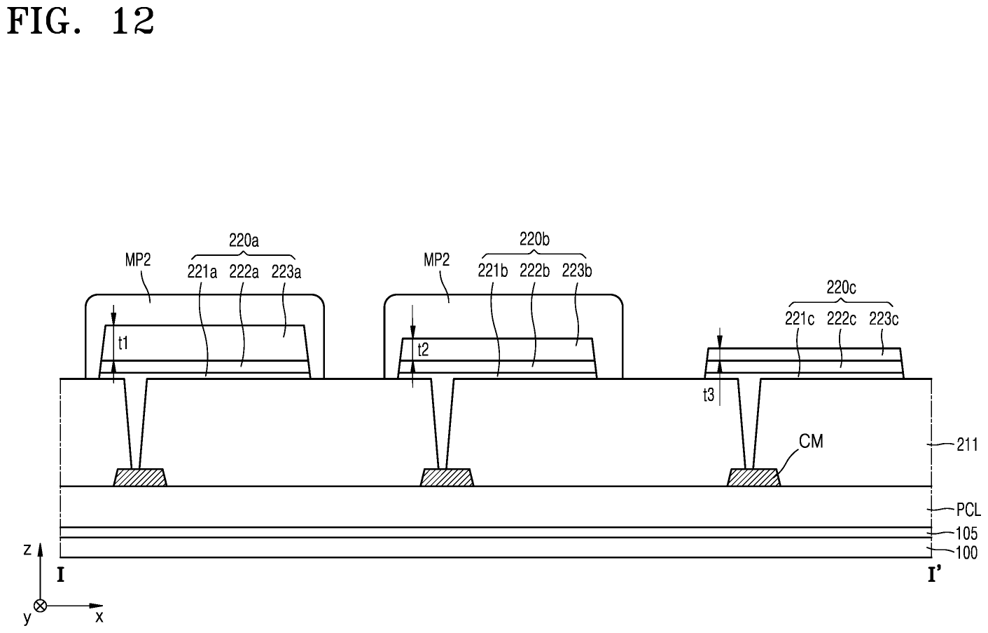

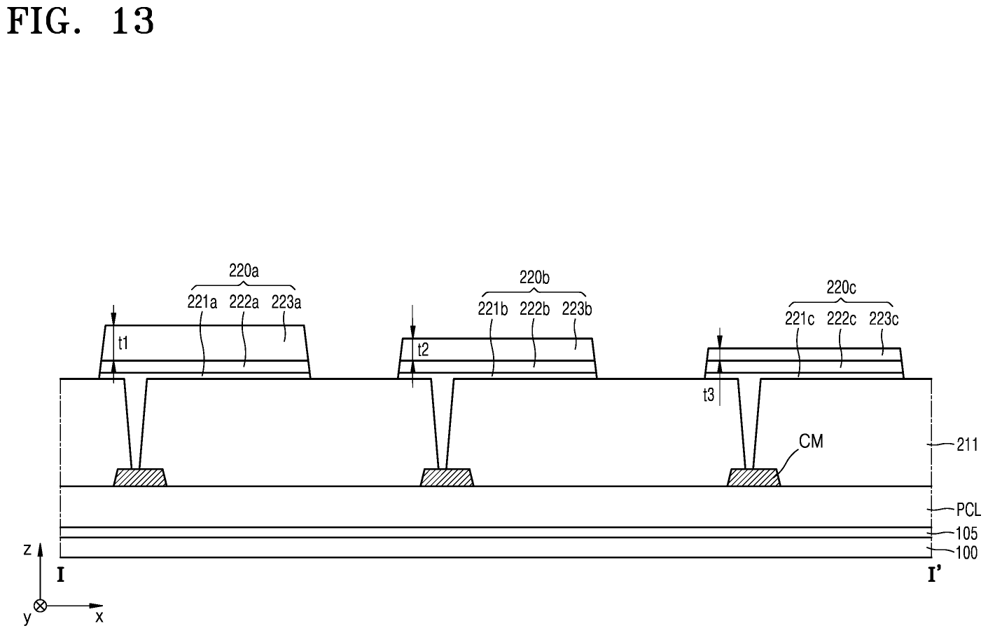

Referring to FIGS. 12 and 13, the second wet etching may be performed after the second mask pattern MP2 is formed to cover and surround the first pixel electrode 220a and the second pixel electrode 220b. The second wet etching may include etching the third conductive layer 223c except for the first conductive layer 223a and the second conductive layer 223b. The second mask pattern MP2 may be formed to prevent the first conductive layer 223a and the second conductive layer 223b from being etched while the third conductive layer 223c of the third pixel electrode 220c is etched. The second mask pattern MP2 may be a positive-type photoresist. However, the disclosure is not limited thereto.

In an embodiment, during the second wet etching, the third conductive layer 223c of the third pixel electrode 220c may be etched to have a thickness of about 600 Å in the thickness direction of the substrate 100. After the first wet etching and the second set etching, the thickness of the first conductive layer 223a of the first pixel electrode 220a may be defined as the first thickness t1 in the thickness direction of the substrate 100. The thickness of the second conductive layer 223b of the second pixel electrode 220b may be defined as the second thickness t2 in the thickness direction of the substrate 100. Also, the thickness of the third conductive layer 223c of the third pixel electrode 220c may be defined as the third thickness t3 in the thickness direction of the substrate 100.

After the first wet etching and the second wet etching, the second thickness t2 of the second conductive layer 223b of the second pixel electrode 220b may be less than the first thickness t1 of the first conductive layer 223a of the first pixel electrode 220a. The third thickness t3 of the third conductive layer 223c of the third pixel electrode 220c may be less than the second thickness t2 of the second conductive layer 223b of the second pixel electrode 220b. In other words, the first thickness t1 of the first conductive layer 223a may be the greatest, and the third thickness t3 of the third conductive layer 223c may be the smallest. The second thickness t2 of the second conductive layer 223b may be intermediate between the first thickness t1 of the first conductive layer 223a and the third thickness t3 of the third conductive layer 223c. In particular, after the first wet etching and the second wet etching, the first thickness t1 of the first conductive layer 223a may be greater than or equal to 1700 Å and less than or equal to 1900 Å, the second thickness t2 of the second conductive layer 223b may be greater than or equal to 1100 Å and less than or equal to 1300 Å, and the third thickness t3 of the third conductive layer 223c may be greater than or equal to 600 Å or less than or equal to 800 Å.

After the second wet etching is performed, the second mask pattern MP2 may be removed. The second mask pattern MP2 is formed to cover and surround the first pixel electrode 220a and the second pixel electrode 220b, so that the first thickness t1 of the first conductive layer 223a and the second thickness t2 of the second conductive layer 223b after the second wet etching may be maintained equal to the first thickness t1 of the first conductive layer 223a and the second thickness t2 of the second conductive layer 223b after the first wet etching.

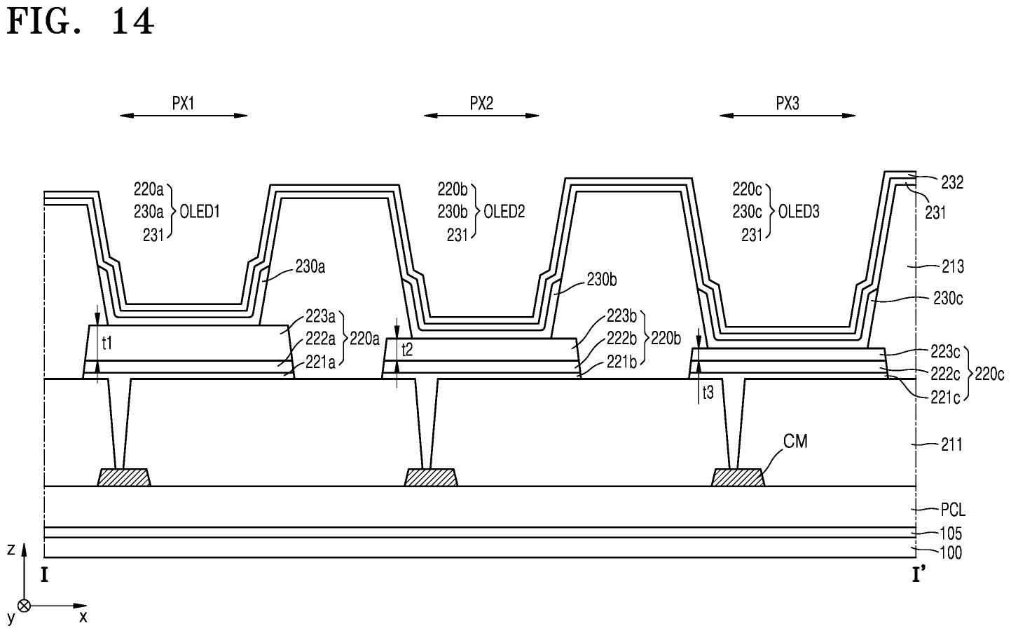

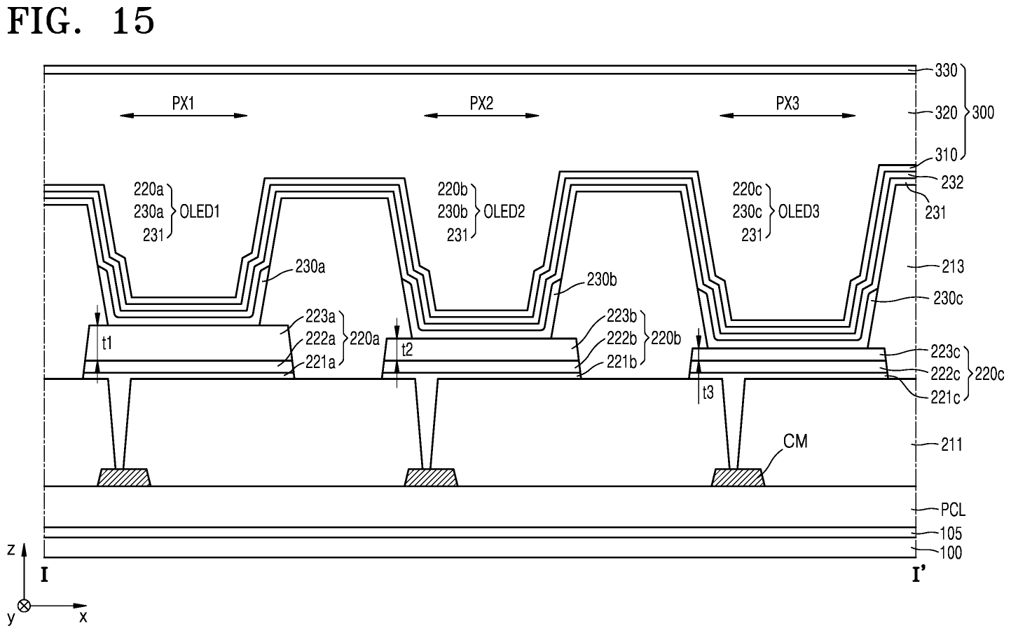

Referring to FIGS. 14 and 15, the pixel defining layer 213 may be disposed on the first to third pixel electrodes 220a, 220b, and 220c. The pixel defining layer 213 may include openings, and at least a portion of the first to third pixel electrodes 220a, 220b, and 220c may be exposed by the openings of the pixel defining layer 213. The first to third emission layers 230a, 230b, and 230c may be arranged in the openings of the pixel defining layer 213. In particular, the first emission layer 230a may be disposed on the first pixel electrode 220a exposed by the opening of the pixel defining layer 213. The second emission layer 230b may be disposed on the second pixel electrode 220b exposed by the opening of the pixel defining layer 213. Also, the third emission layer 230c may be disposed on the third pixel electrode 220c exposed by the opening of the pixel defining layer 213.

In an embodiment, the opposite electrode 231 may be disposed on the first to third emission layers 230a, 230b, and 230c. The opposite electrode 231 may be continuously disposed on the substrate 100. The capping layer 232 may be disposed on the opposite electrode 231. The capping layer 232 may be continuously disposed on the substrate 100. The capping layer 232 may increase reflectance of light emitted from the first to third emission layers 230a, 230b, and 230c at the opposite electrode 231.

The first pixel electrode 220a, the first emission layer 230a, and the opposite electrode 231, which are exposed by the opening of the pixel defining layer 213, may form the first organic light-emitting diode OLED1. The second pixel electrode 220b, the second emission layer 230b, and the opposite electrode 231, which are exposed by the opening of the pixel defining layer 213, may form the second organic light-emitting diode OLED2. The third pixel electrode 220c, the third emission layer 230c, and the opposite electrode 231, which are exposed by the opening of the pixel defining layer 213, may form the third organic light-emitting diode OLED3. The first to third pixels PX1, PX2, and PX3 may respectively include the first to third organic light-emitting diodes OLED1, OLED2, and OLED3.

In an embodiment, the thin-film encapsulation layer 300 may be disposed on the capping layer 232. The thin-film encapsulation layer 300 may include the first inorganic encapsulation layer 310, the second inorganic encapsulation layer 330, and the organic encapsulation layer 320. The organic encapsulation layer 320 may be between the first inorganic encapsulation layer 310 and the second inorganic encapsulation layer 330. However, the disclosure is not limited thereto. In another embodiment, the number of organic encapsulation layers, the number of inorganic encapsulation layers, and a stacking order thereof may be changed.

Organic light-emitting elements of a display device may form a microcavity. When the organic light-emitting elements form a microcavity, light extraction efficiency of light emitted from an emission layer may be improved.

Respective optical resonance distances of light of different wavelength bands emitted from emission layers must be satisfied such that organic light-emitting elements form a microcavity. Accordingly, a microcavity may be formed by adjusting the thickness of a conductive layer of a pixel electrode having an emission layer disposed at a lower portion thereof according to a wavelength range of light emitted by the emission layer, and light extraction efficiency of light emitted from the emission layer may be increased.

According to an embodiment as described above, a display device with improved light extraction efficiency and a method of manufacturing the same may be implemented. The scope of the disclosure is limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate comprising a first pixel, a second pixel, and a third pixel;
a first pixel electrode of the first pixel, which comprises a first reflective layer and a first conductive layer, a second pixel electrode of the second pixel, which comprises a second reflective layer and a second conductive layer, and a third pixel electrode of the third pixel, which comprises a third reflective layer and a third conductive layer, wherein the first pixel electrode, the second pixel electrode, and the third pixel electrode are disposed on the substrate;
a first emission layer of the first pixel, which is disposed on the first pixel electrode, a second emission layer of the second pixel, which is disposed on the second pixel electrode, and a third emission layer of the third pixel, which is disposed on the third pixel electrode; and
an opposite electrode disposed on the first emission layer, the second emission layer, and the third emission layer,
wherein the first conductive layer has a first thickness in a thickness direction of the substrate, and
the second conductive layer has a second thickness less than the first thickness in the thickness direction of the substrate.

2. The display device of claim 1, wherein the third conductive layer has a third thickness less than the second thickness in the thickness direction of the substrate.

3. The display device of claim 2, wherein the first thickness of the first conductive layer is equal to or greater than 1700 angstrom (Å) and equal to or less than 1900 Å,
the second thickness of the second conductive layer is equal to or greater than 1100 Å and equal to or less than 1300 Å, and
the third thickness of the third conductive layer is equal to or greater than 600 Å and equal to or less than 800 Å.

4. The display device of claim 1, further comprising a capping layer disposed on the opposite electrode.

5. The display device of claim 1, wherein the first emission layer, the second emission layer, and the third emission layer emit red light, green light, and blue light, respectively.

6. The display device of claim 1, wherein the first conductive layer, the second conductive layer, and the third conductive layer comprise a same material.

7. The display device of claim 1, wherein the first reflective layer, the second reflective layer, and the third reflective layer comprise a same material.

8. The display device of claim 1, wherein the first conductive layer, the second conductive layer, and the third conductive layer are disposed on the first reflective layer, the second reflective layer, and the third reflective layer, respectively.

9. The display device of claim 7, further comprising a first protective layer, a second protective layer, and a third protective layer directly disposed on lower surfaces of the first reflective layer, the second reflective layer, and the third reflective layer, respectively.

10. The display device of claim 9, wherein the first protective layer, the second protective layer, and the third protective layer comprise a same material.

11. A method of manufacturing a display device, the method comprising:
disposing a material for forming a partition layer on a substrate;
forming a partition layer by patterning the material for forming the partition layer;
disposing a material for forming a reflective layer and a material for forming a conductive layer on the partition layer and in openings defined in the partition layer;
forming a first pixel electrode comprising a first reflective layer and a first conductive layer, a second pixel electrode comprising a second reflective layer and a second conductive layer, and a third pixel electrode comprising a third reflective layer and a third conductive layer by removing the material for forming the reflective layer and the material for forming the conductive layer, which are disposed on the partition layer;
performing first etching in which at least a portion of the second conductive layer and the third conductive layer are wet-etched after forming a first mask pattern to cover and surround the first pixel electrode;
removing the first mask pattern; and
performing second etching in which at least a portion of the third conductive layer is wet-etched after forming a second mask pattern to cover and surround each of the first pixel electrode and the second pixel electrode.

12. The method of claim 11, further comprising:
after performing the second etching in which at least the portion of the third conductive layer is wet-etched after forming the second mask pattern to cover and surround each of the first pixel electrode and the second pixel electrode, removing the second mask pattern.

13. The method of claim 11, wherein the material for forming the partition layer comprises an inorganic material.

14. The method of claim 11, wherein the material for forming the partition layer comprises a photoresist-forming material.

15. The method of claim 14, further comprising:
after the forming of the partition layer by patterning the material for forming the partition layer, removing the partition layer.

16. The method of claim 11, wherein a thickness of each of the first conductive layer, the second conductive layer, and the third conductive layer before performing the first etching is equal to or greater than 1700 angstrom (Å) and equal to or less than 1900 Å.

17. The method of claim 16, wherein the first conductive layer after performing the second etching has a first thickness in a thickness direction of the substrate,
the second conductive layer after performing the second etching has a second thickness less than the first thickness in the thickness direction of the substrate, and
the third conductive layer after performing the second etching has a third thickness less than the second thickness in the thickness direction of the substrate.

18. The method of claim 17, wherein the first thickness of the first conductive layer after performing the second etching is equal to or greater than 1700 Å and equal to or less than 1900 Å,
the second thickness of the second conductive layer after performing the second etching is equal to or greater than 1100 Å and equal to or less than 1300 Å, and
the third thickness of the third conductive layer after performing the second etching is equal to or greater than 600 Å and equal to or less than 800 Å.

19. The method of claim 11, further comprising disposing a first emission layer, a second emission layer, and a third emission layer on the first pixel electrode, the second pixel electrode, and the third pixel electrode, respectively,
wherein the first emission layer, the second emission layer, and the third emission layer emit red light, green light, and blue light, respectively.

20. The method of claim 19, further comprising disposing an opposite electrode on the first emission layer, the second emission layer, and the third emission layer; and
disposing a capping layer on the opposite electrode.
